(19) United States
(12) Patent Application Publication
(10) Pub. No.: US 2007/0196981 A1
(43) Pub. Date: Aug. 23, 2007

(54) Active matrix type liquid crystal display device

(75) Inventors: Chien-Chung Kuo, Feng Yuan City (TW); Yi-Lin Chou, Tai Chung County (TW)

Correspondence Address: BIRCH STEWART KOLASCH & BIRCH, PO BOX 747, FALLS CHURCH, VA, 22040-0747, US

(73) Assignee: WINTEK CORPORATION

(21) Appl. No.: 11/519,086

(22) Filed: Sep. 12, 2006

(30) Foreign Application Priority Data
Feb. 8, 2006 (TW) 095104149

(51) Int. Cl. H01L 21/8242

(52) U.S. Cl. 438/253

(57) ABSTRACT

An active matrix type liquid crystal display includes a first substrate, a second substrate, and a liquid crystal layer interposed between them. A plurality of common lines are provided on the second substrate, and a first dielectric layer provided with contact holes is fonned on the second substrate and covers the common lines. Capacitor electrodes connected to the common lines via the contact holes are provided on the first dielectric layer, and a second dielectric layer is formed overlying the capacitor electrodes. Pixel electrodes are formed on the second dielectric layer, and each pixel electrode together with each capacitor electrode form a storage capacitor.

### CROSS REFERENCE TO RELATED PATENT APPLICATION

The present application claims priority under 35 U.S.C. §119(a) on Patent Application No. 095104149 filed in Taiwan on Feb. 8, 2006, the entire contents of which are hereby incorporated by reference.

### BACKGROUND OF THE INVENTION

(a) Field of the Invention

The invention relates to an active matrix type liquid crystal display (AM LCD) device having a high aperture ratio.

(b) Description of the Related Art

At present, the dominant method for fabricating an active matrix liquid crystal display device is typically based on amorphous silicon thin film transistor (a-Si TFT) technologies.

FIG. 1A shows a plan view illustrating a conventional active matrix display device 100. FIG. 1B shows a cross-sectional view of the active matrix display device shown in FIG. 1A, taken along line A-A′. Referring to FIG. 1A, the gate 102g of an n-type a-Si TFT 102 is connected to a gate line 106, its source 102s is connected to a data line 106, and its drain 102d is connected to a pixel electrode 110 via a contact hole 108. A storage capacitor Cst is formed between a pixel electrode 110 and a common line 112 with a gate insulation layer 114 and a passivation layer 116 interposed between them, as best shown in FIG. 1B. The common line 112 functioning as a capacitor electrode is formed from a Metal 1 layer during the fabrication of the a-Si TFT 102 and accompanied by the formation of the gate 102g of the a-Si TFT 102.

As will be understood by those skilled in the art, the value of the storage capacitor Cst depends on of the area of overlap between the pixel electrode 110 and the common line 112, the gap spacing between the two opposite capacitor electrodes, and the dielectric constants of the interposed dielectric layers 114 and 116. However, as shown in FIG. 1B, since the dielectric layers interposed between two capacitor electrodes include both the gate insulation layer 114 and the passivation layer 116 to result in a great thickness, the spread area of the lower capacitor electrode (common lines) 112 which in turn must be increased so as to provide sufficient storage capacitance. This may result in a significant decrease of the aperture ratio for the display device because the capacitor electrode is made of opaque metallic materials.

FIG. 2A shows a plan view illustrating another conventional active matrix display device 200, and FIG. 2B shows a cross-sectional view of the active matrix display device shown in FIG. 2A, taken along line B-B′. Referring to FIG. 2A, the gate 202g of a n-type a-Si TFT 202 is connected to a gate line 204, its source 202s is connected to a data line 206, and its drain 202d is connected to a pixel electrode 212 via a contact hole 220. A storage capacitor Cst is formed between a lower capacitor electrode 208 and an upper capacitor electrode 210, and the upper electrode 210 is connected to the pixel electrode 212 via a contact hole 214, as best shown in FIG. 2B. The lower electrode 208 is formed from a Metal 1 layer and accompanied by the formation of the gate 202g of the a-Si TFT 202, while the upper electrode 210 is formed from a Metal 2 layer and accompanied by the formation of the source 202s and drain 202d of the a-Si TFT 202.

Referring to FIG. 2B, since only the gate insulation layer 216, without the passivation layer 218, is interposed between the lower capacitor electrode 208 and upper capacitor electrode 210, the gap spacing between the two capacitor electrodes is smaller compared to the storage capacitor design shown in FIG. 1B to permit a reduction of the spread areas of the capacitor electrodes. However, in practical fabrication processes of an array substrate, when the storage capacitor design shown in FIG. 2B is adopted with a limited fabrication tolerance taken into consideration, the lower capacitor electrode 208 normally is formed to have a larger area than needed to cover the upper capacitor electrode 210 so as to avoid the residual conductive particles left on the gate insulation layer 216. Hence, this may result in a significant decrease of the aperture ratio for the display device and a waste of metallic materials.

### BRIEF SUMMARY OF THE INVENTION

Hence, an object of the invention is to provide an active matrix type liquid crystal display device that has a high aperture ratio. [00091 According the invention, the display device includes a first substrate, a second substrate, and a liquid crystal layer interposed between the first substrate and the second substrate. A common electrode is provided on the first substrate, and a plurality of first signal lines and common lines are provided on the second substrate. A first dielectric layer is formed on the second substrate and covers the first signal lines and the common lines, and the first dielectric layer is provided with a plurality of contact holes to expose part of the common lines. A plurality of second signal lines and capacitor electrodes are provided on the first dielectric layer, and the capacitor electrodes are connected to the common lines via the contact holes. A plurality of switching devices are provided in the vicinity of each intersection of the first and the second signal lines, and a second dielectric layer is formed overlying the second signal lines and the capacitor electrodes. A plurality of pixel electrodes are formed on the second dielectric layer, and each of the pixel electrodes together with each of the capacitor electrodes form a storage capacitor.

Through the design of the invention, since the two capacitor electrodes of a storage capacitor are separated from each other only by the passivation layer, a smaller area of the capacitor electrode can be selected to maintain sufficient storage capacitance. Thus, the spread areas of opaque metallic films are decreased to result in a high aperture ratio. On the other hand, the extra areas of the lower capacitor electrode, which may be provided for maintaining a proper positioning to eliminate residual conductive particles, are no longer needed, since the upper capacitor electrode of the invention is the pixel electrode that spreads on an entire pixel area. Moreover, in typical fabrication processes of an array substrate, the deposition thickness of the passivation layer is often smaller than that of the gate insulation layer, and thus the area of the capacitor electrode is further reduced to increase the aperture ratio while maintaining the same storage capacitance.

### BRIEF DESCRIPTION OF THE DRAWINGS

FIG. 1A shows a plan view illustrating a conventional active matrix display device. FIG. 1B shows a cross-sectional view of the active matrix display device shown in FIG. 1A, taken along line A-A′.

FIG. 2A shows a plan view illustrating another conventional active matrix display device, and FIG. 2B shows a cross-sectional view of the active matrix display device shown in FIG. 2A, taken along line B-B′.

FIG. 3 shows a partial cross-sectional view illustrating an active matrix type liquid crystal display device according to the invention.

FIGS. 4A and 4B show schematic diagrams illustrating an embodiment of a pixel structure of an active matrix display device according to the invention, and FIG. 4C shows an equivalent circuit diagram of one pixel structure according to the invention.

FIG. 5 shows a plan view illustrating another embodiment of the invention.

FIG. 6 shows a plan view illustrating another embodiment of the invention.

### DETAILED DESCRIPTION OF THE INVENTION

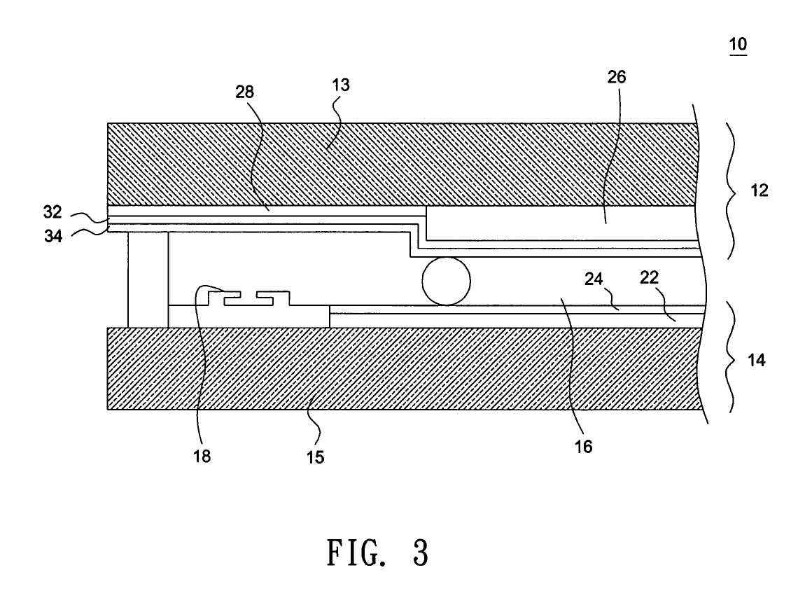

FIG. 3 shows a partial cross-sectional view illustrating an active matrix type liquid crystal display (AM LCD) device 10 according to the invention. Referring to FIG. 3, the display device 10 includes a color filter substrate 12 and an array substrate 14, with a liquid crystal layer 16 interposed between them. In the array substrate 14, a switching device such as a thin film transistor (TFT) 18, a pixel electrode 22, and a first alignment layer 24 are formed on a transparent substrate 15. Further, in the color filter substrate 12, a color filter 26, a black matrix layer 28, a common electrode 32, and a second alignment layer 34 are formed on a transparent substrate 13.

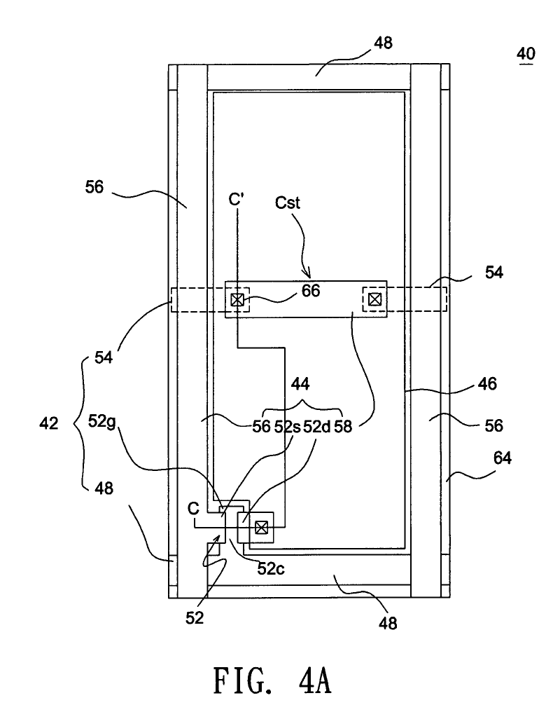

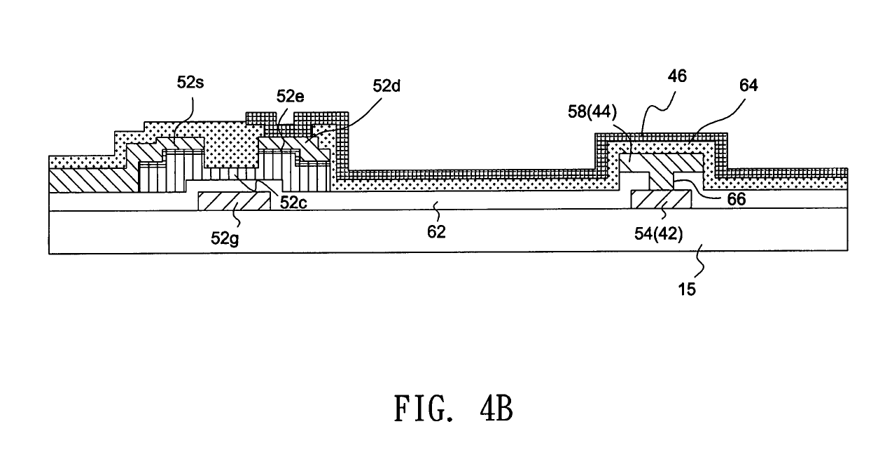

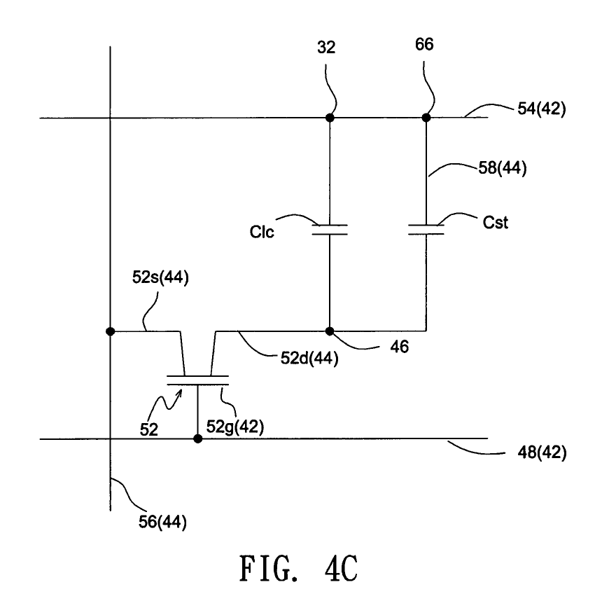

FIGS. 4A and 4B show schematic diagrams illustrating an embodiment of a pixel structure 40 of an active matrix display device according to the invention, where FIG. 4A shows a plan view observed from the normal direction of an array substrate, and FIG. 4B shows a cross-sectional view taken along line C-C′ in FIG. 4A.

Referring to FIG. 4A, a plurality of gate lines 48 are arranged extending in a first direction, and a plurality of data lines 56 are arranged extending in a second direction perpendicular to the first direction, with each two gate lines 48 intersected with each two data lines 56 to define a pixel area on the array substrate 14. A pixel electrode made from transparent conductive films is formed on each pixel area, and the transparent conductive films may be made from indium tin oxide (ITO) or indium zinc oxide (IZO). A switching device such as an amorphous silicon thin film transistor (a-Si TFT) 52 is formed in the vicinity of each intersection of the gate lines 48 and the data lines 56.

Referring to both FIGS. 4A and 4B, a Metal 1 layer 42 made from Cr, Ta, or Al/Mo metallic films is deposited on the transparent substrate 15 and patterned to define the gate lines 48, the gate 52g of the a-Si TFT 52, and common lines 54. A dielectric gate insulation layer 62 is formed overlying the Metal 1 layer 42; for instance, the gate insulation layer 62 may be formed on the Metal 1 layer 42 by depositing silicon nitride (SiNx), silicon oxide (SiOx) or silicon oxynitride (SiOxNy).

A channel region 52c (pure amorphous silicon (a-Si)), an ohmic contact layer 52e (doped amorphous silicon (n+a-Si)) and a Metal 2 layer 44 are formed on the gate insulation layer 62, with the Metal 2 layer 44 being formed overlying the channel region 52c and the ohmic contact layer 52e. Specifically, the Metal 2 layer 44 made from Al/Cr, Al/Ti, Ti, or Mo/Al/Mo metallic films is sputtered on the gate insulation layer 62 and patterned to define the source 52s and the drain 52d of the a-Si TFT 52, the data lines 56, and a capacitor electrode 58. The source 52s and the drain 52d of the a-Si TFT 52 are provided at two sides of the channel region 52c and respectively connected to the data lines 56 and a pixel electrode 46, and the gate 52g of the a-Si TFT 52 is connected to the gate lines 48.

A dielectric passivation layer 64 is formed overlying the gate insulation layer 62 and the Metal 2 layer 44 to cover the source 52s and the drain 52d of the a-Si TFT 52, the data lines 56, and the capacitor electrode 58. The passivation layer 64 may be made from silicon nitride (SiNx), silicon oxide (SiOx) or silicon oxynitride (SiOxNy). Then, transparent conductive films made from indium tin oxide (ITO) or indium zinc oxide (IZO) are deposited on the passivation layer 64 and patterned to form the pixel electrode 46.

As shown in FIG. 4B, a storage capacitor Cst in the pixel structure 40 is formed between the pixel electrode 46 and the capacitor electrode 58 made from the Metal 2 layer 44, with the passivation layer 64 interposed between them. Further, a portion of the gate insulation layer 62 is removed to expose part common lines 54 and form a contact hole 66, and the capacitor electrode 58 made from the Metal 2 layer 44 is electrically connected to the common lines 54 made from the Metal 1 layer 42 through the contact hole 66.

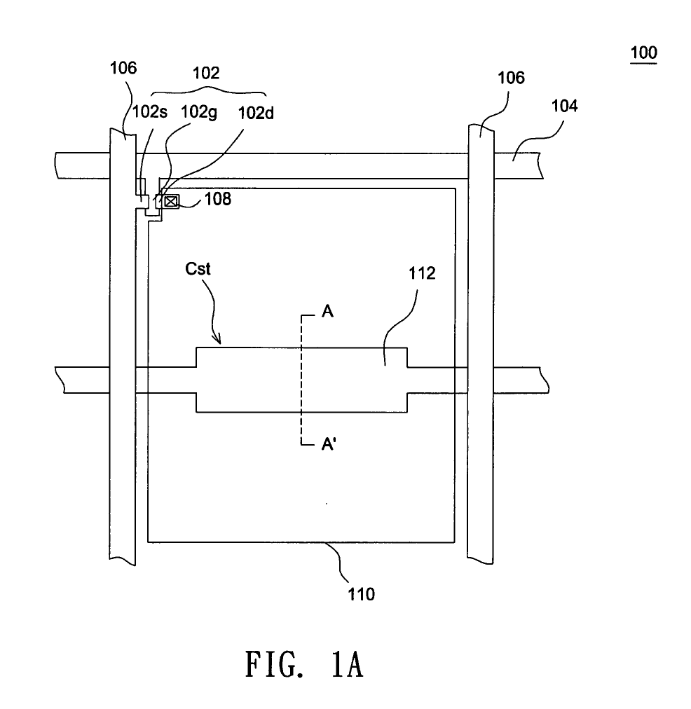

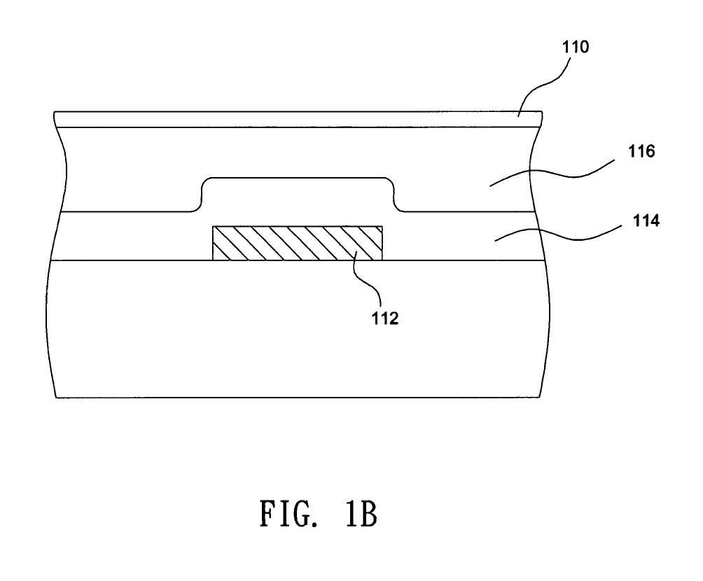

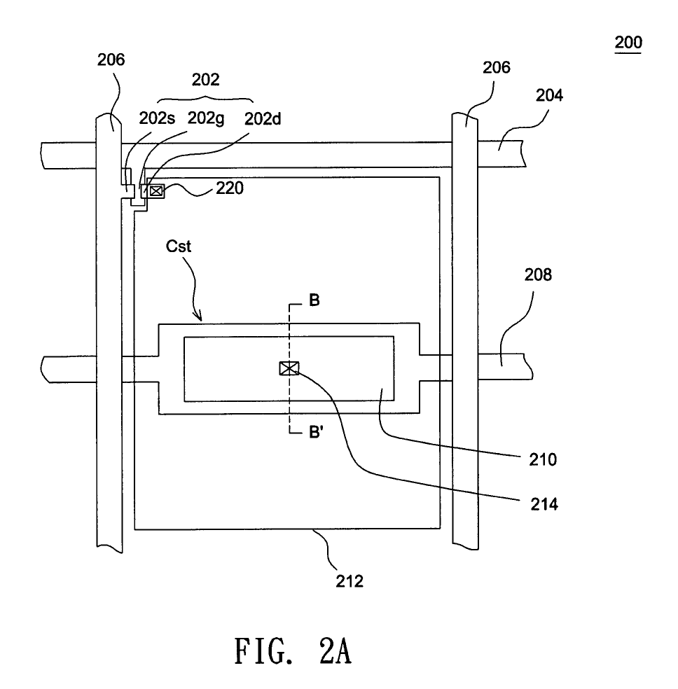

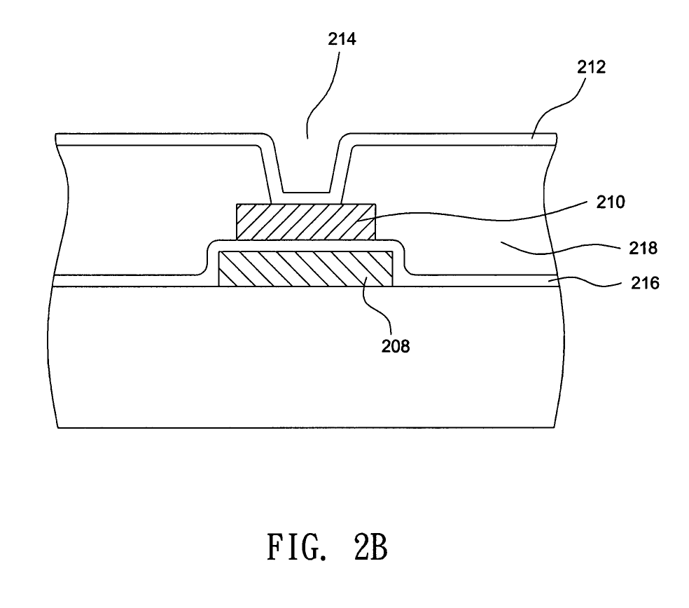

According to the invention, since the two capacitor electrodes, made from the Metal 2 layer 44 and the pixel electrode 46, are separated from each other only by the passivation layer 64, a smaller area of the capacitor electrode 58 compared to the conventional design shown in FIG. 1B can be selected to maintain the same storage capacitance. Thus, the spread areas of opaque metallic films are decreased to result in a high aperture ratio. On the other hand, the extra areas of the lower capacitor electrode, which are provided for maintaining a proper positioning to eliminate residual conductive particles as mentioned in the conventional design of FIG. 2B, are no longer needed, since the upper capacitor electrode of the invention is the pixel electrode 46 that spreads on an entire pixel area. Moreover, in typical fabrication processes of an array substrate, the deposition thickness of the passivation layer 64 is often smaller than that of the gate insulation layer 62, and thus the area of the capacitor electrode 58 can be further reduced to increase the aperture ratio while maintaining the same storage capacitance.

FIG. 4C shows an equivalent circuit diagram of one pixel structure according to the invention, where the electrical connection between the storage capacitor Cst and other elements is clearly seen. Referring to FIG. 4C, the gate 52g of the a-Si TFT 52 is connected to the gate line 48, its source 52s is connected to the data line 56, and its drain 52d is connected to the pixel electrode 46. The common line 54 is connected to a common electrode 32 formed on the color filter substrate 12, and they are connected to a common voltage Vcom or a reference voltage. The gate line 48 transfers scanning signals or gate signals, and the data line 56 transfers image signals or data signals. The LC capacitor Clc is formed between the pixel electrode 46 on the array substrate 14 and the common electrode 32 on the color filter substrate 12. The storage capacitor Cst is formed between the capacitor electrode 58 made from the Metal 2 layer 44 and the pixel electrode 46, and the capacitor electrode 58 is connected to the common lines 54 made from the Metal 1 layer 42 via the contact hole 66.

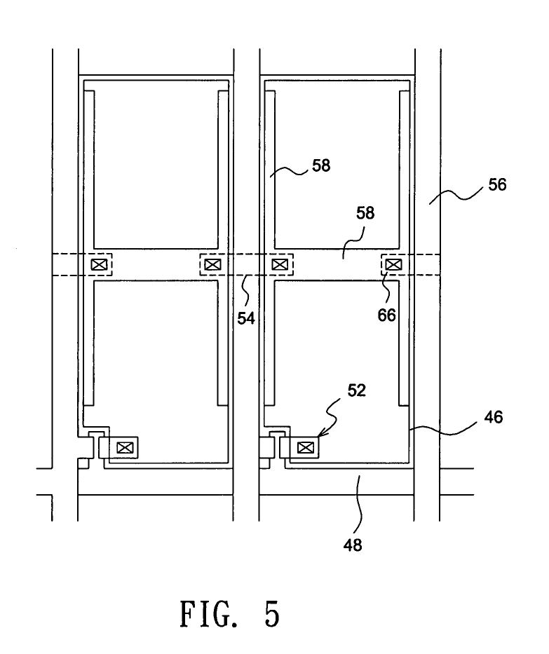

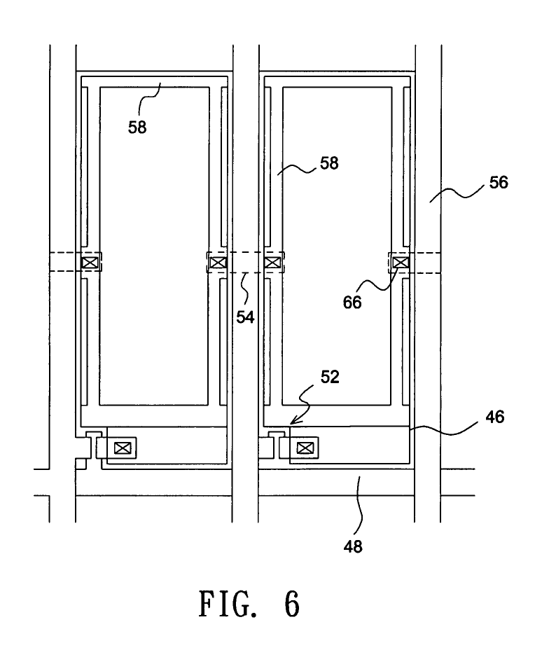

Though the capacitor electrode 58 shown in FIG. 4A is exemplified as horizontally extending in the middle of the pixel area, the distribution of the capacitor electrode 58 on an array substrate is not limited according to the invention. For example, as shown in FIG. 5, the capacitor electrode 58 may extend in a vertical direction and next to the data lines 56 to block the abnormal light leakage, which is caused by the orientation disorder of the liquid crystal molecules in the vicinity of the periphery of the pixel electrode where the vertically-applied electric field is often distorted. In that case, the capacitor electrode 58 may function as a light-blocking structure. Certainly, the shape, area, and thickness of the capacitor electrode 58 are not limited and can be arbitrary selected to obtain optimal light-shielding effect. For example, as shown in FIG. 6, the capacitor electrode 58 may include multiple strip-shaped sections placed on the four edges of one pixel to avoid the abnormal light leakage due to all kinds of factors.

While the invention has been described by way of examples and in terms of the preferred embodiments, it is to be understood that the invention is not limited to the disclosed embodiments. To the contrary, it is intended to cover vanous modifications and similar arrangements as would be apparent to those skilled in the art. For example, the gate lines 48 may be made from the Metal 2 layer, and the data lines 56 may be made from the Metal 1 layer. Therefore, the scope of the appended claims should be accorded the broadest interpretation so as to encompass all such modifications and similar arrangements.

What is claimed is:

1. An active matrix type liquid crystal display device, comprising:
a first substrate;
a second substrate facing the first substrate;
a liquid crystal layer interposed between the first substrate and the second substrate;
a common electrode provided on the first substrate;
a plurality of first signal lines and common lines provided on the second substrate;
a first dielectric layer formed on the second substrate and covering the first signal lines and the common lines, the first dielectric layer having a plurality of contact holes to expose part of the common lines;
a plurality of second signal lines and capacitor electrodes provided on the first dielectric layer, the capacitor electrodes being connected to the common lines via the contact holes;
a plurality of switching devices, each of which is provided in the vicinity of each intersection of the first and the second signal lines;
a second dielectric layer formed overlying the second signal lines and the capacitor electrodes; and
a plurality of pixel electrodes formed on the second dielectric layer; wherein each of the pixel electrodes together with each of the capacitor electrodes form a storage capacitor.

2. The active matrix type liquid crystal display device as claimed in claim 1, wherein the first signal lines are gate lines and the second signal lines are data lines.

3. The active matrix type liquid crystal display device as claimed in claim 1, wherein the first signal lines are data lines and the second signal lines are gate lines.

4. The active matrix type liquid crystal display device as claimed in claim 1, wherein the first dielectric layer is a gate insulation layer and the second dielectric layer is a passivation layer.

5. The active matrix type liquid crystal display device as claimed in claim 1, wherein the first and the second dielectric layers are made from silicon nitride (SiNx), silicon oxide (SiOx) or silicon oxynitride (SiOxNy), and the pixel electrode is made from indium tin oxide (ITO) or indium zinc oxide (IZO).

6. The active matrix type liquid crystal display device as claimed in claim 1, wherein the second dielectric layer is thinner than the first dielectric layer.

7. The active matrix type liquid crystal display device as claimed in claim 1, wherein the switching device is an amorphous silicon thin film transistor (a-Si TFT).

8. The active matrix type liquid crystal display device as claimed in claim 1, wherein the capacitor electrodes function as a light-blocking structure.

9. The active matrix type liquid crystal display device as claimed in claim 1, wherein the capacitor electrode includes at least one strip-shaped section.

10. The active matrix type liquid crystal display device as claimed in claim 9, wherein the strip-shaped section is positioned next to the signal lines.

11. A pixel structure having a storage capacitor, comprising:
a Metal 1 layer formed on a transparent substrate and patterned to define common lines, gate lines, and the gate of a thin film transistor;
a first dielectric layer formed overlying the Metal 1 layer and having at least one contact hole to expose part of the Metal 1 layer;
a Metal 2 layer formed on the first dielectric layer and patterned to define data lines, the drain and the source of the thin film transistor, and a first capacitor electrode of the storage capacitor, the first capacitor electrode being connected to the Metal 1 layer through the contact hole;
a second dielectric layer formed overlying the Metal 2 layer; and
a pixel electrode formed on the second dielectric layer and functioning as a second capacitor electrode of the storage capacitor.

12. The pixel structure as claimed in claim 11, wherein the first dielectric layer is a gate insulation layer and the second dielectric layer is a passivation layer.

13. The pixel structure as claimed in claim 12, wherein the first capacitor electrode is connected to the common lines via the contact hole formed on the gate insulation layer.

14. The pixel structure as claimed in claim 11, wherein the Metal 1 layer is made from Cr, Ta, or Al/Mo metallic films, and the Metal 2 layer is made from Al/Cr, Al/Ti, Ti, or Mo/Al/Mo metallic films.

15. The pixel structure as claimed in claim 11, wherein the capacitor electrode functions as a light-blocking structure of the pixel structure.

16. The pixel structure as claimed in claim 15, wherein the light-blocking structure includes at least one strip-shaped section positioned next to the data lines.

17. An active matrix substrate, comprising:
a plurality of gate lines formed on a transparent substrate;
a plurality of data lines formed on the transparent substrate and extending in a direction intersecting a direction in which the gate lines extend;
a plurality of switching devices, each of which is provided in the vicinity of each intersections of the gate lines and the data lines;
a plurality of common lines formed on the transparent substrate and connected to a common electrode;
a first dielectric layer formed overlying the common lines and having a plurality of contact holes to exposed part of the common lines;
a light-blocking metallic film formed on the first dielectric layer and connected to the common lines via the contact holes;
a second dielectric layer formed overlying the light-blocking metallic film; and a plurality of pixel electrodes formed on the second dielectric layer;
wherein each of the pixel electrode together with the light-blocking metallic film form a storage capacitor on the active matrix substrate.

18. The active matrix substrate as claimed in claim 17, wherein the common lines are formed from a Metal 1 layer, and the light-blocking metallic film is formed from a Metal 2 layer.

19. The active matrix substrate as claimed in claim 17, wherein the second dielectric layer is thinner than the first dielectric layer.

20. The active matrix substrate as claimed in claim 17, wherein the light-blocking metallic film includes at least one strip-shaped section positioned next to the data lines.
